(19) United States
(12) Patent Application Publication
(10) Pub. No.: US 2025/0393170 A1
(43) Pub. Date: Dec. 25, 2025

(54) Server System Thermal System

(71) Applicant: Dell Products L.P., Round Rock, TX (US)

(72) Inventors: Yi-Chang Chen, New Taipei City (TW); Yufeng Lin, Taipei City (TW); Haocheng Ku, Taipei City (TW)

(21) Appl. No.: 18/748,692

(22) Filed: Jun. 20, 2024

(51) Int. Cl. H05K 7/20

(52) U.S. Cl. CPC H05K 7/20727; H05K 7/20145

(57) ABSTRACT

An information handling system thermal system. The thermal system includes a fan cage and a fan cage side wall system positioned between the fan cage and a wall of an information handling system chassis, the fan cage side wall system comprising a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system; a front housing component; and, a bottom housing component, the bottom housing component being physically coupled between the rear housing component and the front housing component.

### BACKGROUND OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for a server type information handling system with a server thermal system.

In one embodiment, the invention relates to a fan cage side wall system comprising a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system; a front housing component; and, a bottom housing component, the bottom housing component being physically coupled between the rear housing component and the front housing component.

In another embodiment, the invention relates to a thermal system comprising a fan cage and a fan cage side wall system positioned between the fan cage and a wall of an information handling system chassis, the fan cage side wall system comprising a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system; a front housing component; and, a bottom housing component, the bottom housing component being physically coupled between the rear housing component and the front housing component.

In another embodiment, the invention relates to a system comprising: a processor; a data bus coupled to the processor; and, a thermal system comprising a fan cage and a fan cage side wall system positioned between the fan cage and a wall of an information handling system chassis, the fan cage side wall system comprising a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system; a front housing component; and, a bottom housing component, the bottom housing component being physically coupled between the rear housing component and the front housing component.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a top view of a thermal system including a fan cage as well as fan cage side wall components.

FIGS. 5A and 5B, generally referred to as FIG. 5, show perspective views of an internal portion of a server system having a fan cage side wall system in an open configuration and a closed configuration, respectively.

FIGS. 6A, 6B, and 6C, generally referred to as FIG. 6, show perspective views of a fan cage side wall system in an open configuration and a closed configuration, respectively.

FIGS. 7A and 7B, generally referred to as FIG. 7, respectively show a perspective view of an internal portion of a server system having a fan cage side wall system in cable pass through configuration, a side view of an internal portion of a server system having a fan cage side wall system in cable pass through configuration, a perspective view of an internal portion of a server system having a fan cage side wall system in a cableless configuration, and a side view of an internal portion of a server system having a fan cage side wall system in a cableless configuration.

FIGS. 8A, 8B, 8C, 8D, 8E, 8F and 8G, generally referred to as FIG. 8, respectively show a perspective view, a top view, a bottom view, a front view, a rear view, a left view and a right view of a fan cage side wall system in an open configuration.

FIGS. 9A, 9B, 9C, 9D, 9E, 9F and 9G, generally referred to as FIG. 9, respectively show a perspective view, a top view, a bottom view, a front view, a rear view, a left view and a right view of a fan cage side wall system in a closed configuration.

### DETAILED DESCRIPTION

Various aspects of the disclosure include an appreciation that it is known to provide server type information handling systems with thermal systems which include a server fan component. Various aspects of the present disclosure include an appreciation that server fan components often include a fan cage which holds a plurality of fan devices as well as one or more fan holders. Various aspects of the disclosure include an appreciation that known fan holders often include a side wall block which functions as a fan cage holder, cable container, or a combination thereof. Various aspects of the disclosure include an appreciation that known side wall blocks often require a thermal sealing solution, such as a sponge, positioned between the side wall block and the server fan component.

Various aspects of the disclosure include an appreciation that using such a thermal sealing solution can present certain design challenges as a side wall block with sealing sponge often cannot accommodate all cable configurations. Additionally, the sponge often needs to fill space between the side wall block and the fan server component when no cable is populated to prevent airflow leakage and reduce any thermal performance impact. Additionally known thermal sealing solutions only function with a limited number of cables. For example, certain known thermal sealing solutions can contain a maximum of two PCIe cables. In some server configurations, more than two cables need to pass through this side wall block. Various aspects of the disclosure include an appreciation that excessive cables installed in the holder can deform the holder cover and impact fan cage installation. Accordingly, various aspects of the present disclosure include an appreciation that it would be desirable to provide a sealing solution which accommodates more cables while also fulfilling thermal sealing requirements.

A system and method are disclosed for providing a server thermal system that includes a fan cage as well as an improved fan cage side wall component. In certain embodiments, the fan cage side wall system includes a rotational flapper. In certain embodiments, the rotational flapper extends from a rear wall of the side wall block. In certain embodiments, the rotational flapper may be set to an open orientation when the side wall block is populated with cables. In certain embodiments, the rotational flapper may be set to a closed orientation when the side wall block is not populated with cables. In certain embodiments, the rotational flapper being set to the closed orientation to prevent airflow through the side wall block, thus improving the thermal performance of the fan cage side wall component.

In certain embodiments, the rotational flapper is configured to include a thermal sealing component which thermally seals the fan cage side wall system when the side wall block is populated with cables. In certain embodiments, the thermal sealing component includes a thermal sponge. In certain embodiments, the thermal sponge is thinner than previous thermal sealing solutions.

In certain embodiments, the fan cage side wall system functions as a side wall block which can accommodate various numbers of cables. In various embodiments, the fan cage side wall system can be sized to function with 1U, 2U, 3U or 4U server configurations.

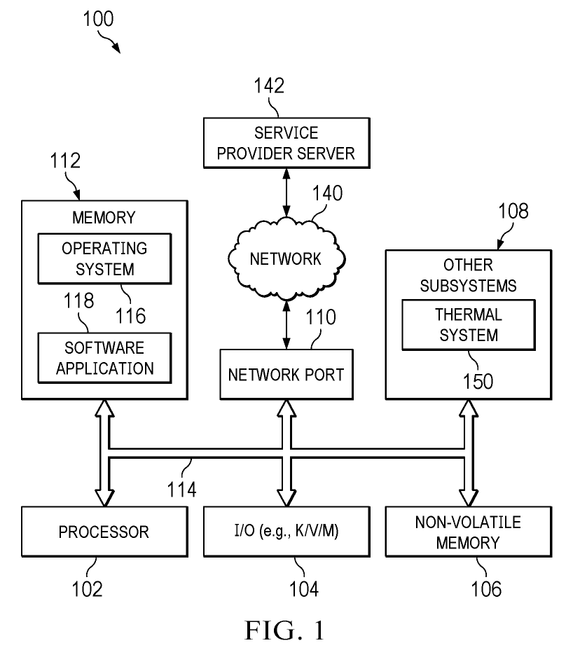

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include fan system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the thermal fan system 150 includes a fan cage as well as at least one improved fan cage side wall component. In certain embodiments, the fan cage side wall system includes a rotational flapper. In certain embodiments, the rotational flapper extends from a rear wall of the side wall block. In certain embodiments, the rotational flapper may be set to an open orientation when the side wall block is populated with cables. In certain embodiments, the rotational flapper may be set to a closed orientation when the side wall block is not populated with cables. In certain embodiments, the rotational flapper being set to the closed orientation to prevent airflow through the side wall block, thus improving the thermal performance of the fan cage side wall component.

In certain embodiments, the rotational flapper is configured to include a thermal sealing component which thermally seals the fan cage side wall system when the side wall block is populated with cables. In certain embodiments, the thermal sealing component includes a thermal sponge. In certain embodiments, the thermal sponge is thinner than previous thermal sealing solutions.

In certain embodiments, the fan cage side wall system functions as a side wall block which can accommodate various numbers of cables. In various embodiments, the fan cage side wall system can be sized to function with 1U, 2U, 3U or 4U server configurations.

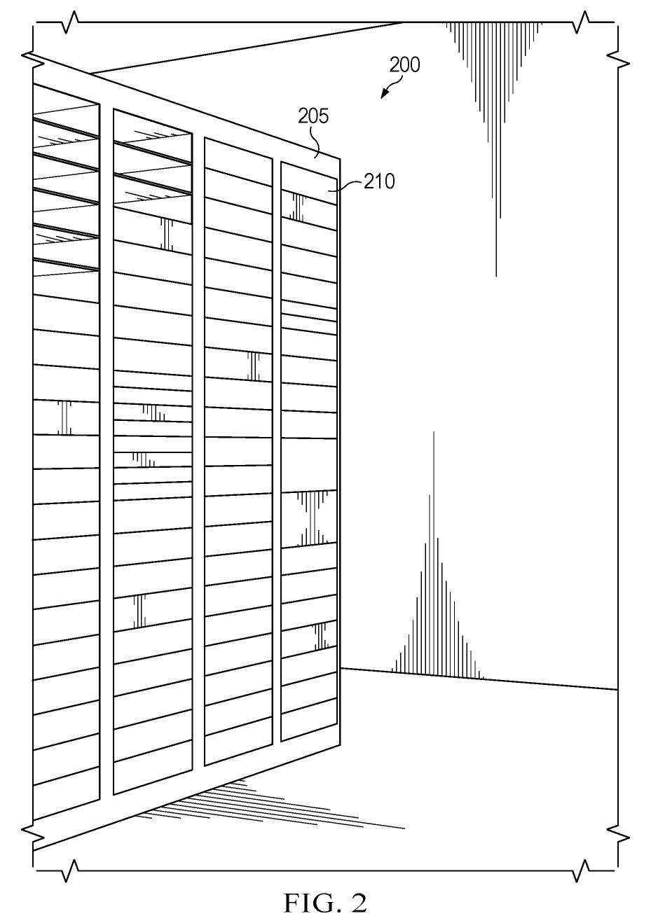

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/-20%) 1.75” high, a 2U rack unit is substantially (i.e., +/-20%) 3.5” high and a 4U rack height is substantially (i.e., +/-20%) 7.0” high.

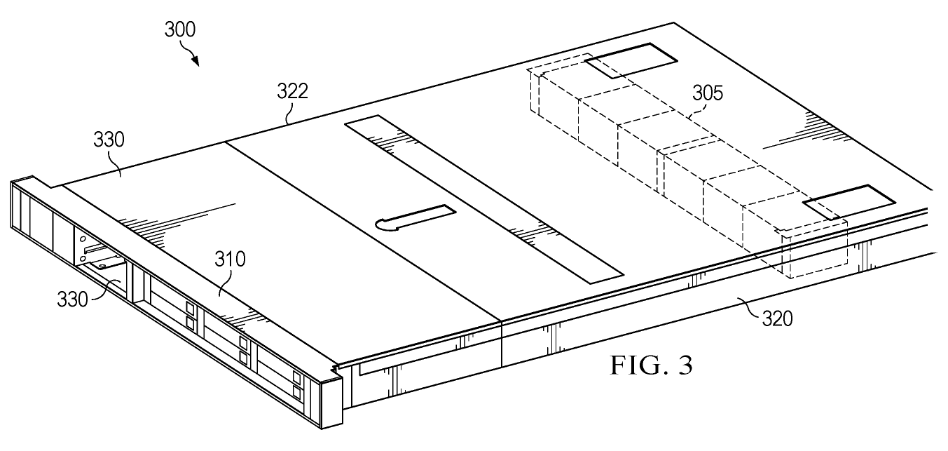

FIG. 3 shows a generalized perspective view of an example server type information handling system 300 which includes a fan system 305. In certain embodiments, the thermal system 305 corresponds to thermal system 150.

In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the server type information handling system 300 may be accessed by removing a top panel 330 of the server type information handing system 300. In certain embodiments, the server type information handing system 300 includes a bay 350 via which components may be mounted to the server type information handling system. In certain embodiments, the server type information handling system includes an integrated fan system 305. In certain embodiments, the server type information handling system 300 is a 2U rack unit server type information handling system.

In certain embodiments, the server fan system 305 includes a fan cage as well as an improved fan cage side wall component. In certain embodiments, the fan cage side wall system includes a rotational flapper. In certain embodiments, the rotational flapper extends from a rear wall of the side wall block. In certain embodiments, the rotational flapper may be set to an open orientation when the side wall block is populated with cables. In certain embodiments, the rotational flapper may be set to a closed orientation when the side wall block is not populated with cables. In certain embodiments, the rotational flapper being set to the closed orientation to prevent airflow through the side wall block, thus improving the thermal performance of the fan cage side wall component.

In certain embodiments, the rotational flapper is configured to include a thermal sealing component which thermally seals the fan cage side wall system when the side wall block is populated with cables. In certain embodiments, the thermal sealing component includes a thermal sponge. In certain embodiments, the thermal sponge is thinner than previous thermal sealing solutions.

In certain embodiments, the fan cage side wall system functions as a side wall block which can accommodate various numbers of cables. In various embodiments, the fan cage side wall system can be sized to function with 1U, 2U, 3U or 4U server configurations.

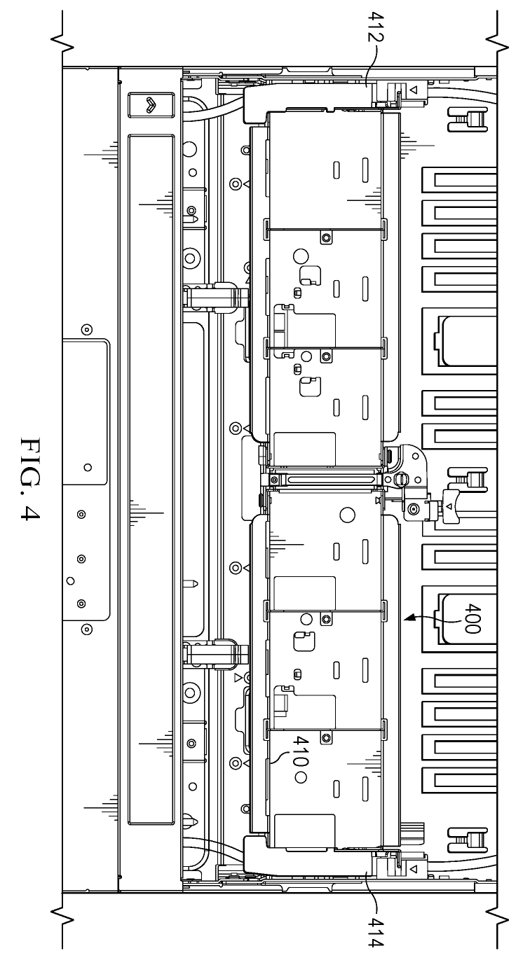

FIG. 4 shows a top view of a thermal system 400 including a fan cage 410 as well as a first fan cage side wall system 412, a second fan cage side component 414, or a combination thereof. In certain embodiments, each fan cage side wall system 412, 414 includes a rotational flapper. In certain embodiments, the rotational flapper extends from a rear wall of the side wall block. In certain embodiments, the rotational flapper may be set to an open orientation when the side wall block is populated with cables. In certain embodiments, the rotational flapper may be set to a closed orientation when the side wall block is not populated with cables. In certain embodiments, the rotational flapper being set to the closed orientation to prevent airflow through the side wall block, thus improving the thermal performance of the fan cage side wall component.

In certain embodiments, the rotational flapper is configured to include a thermal sealing component which thermally seals the fan cage side wall system when the side wall block is populated with cables. In certain embodiments, the thermal sealing component includes a thermal sponge. In certain embodiments, the thermal sponge is thinner than previous thermal sealing solutions.

In certain embodiments, the first fan cage side wall system 412, the second fan cage side wall system 414, or a combination thereof, function as side wall blocks which can each accommodate various numbers of cables. In various embodiments, the first fan cage side wall system 412, the second fan cage side wall system 414, or a combination thereof, can be sized to function with 1U, 2U, 3U or 4U server configurations.

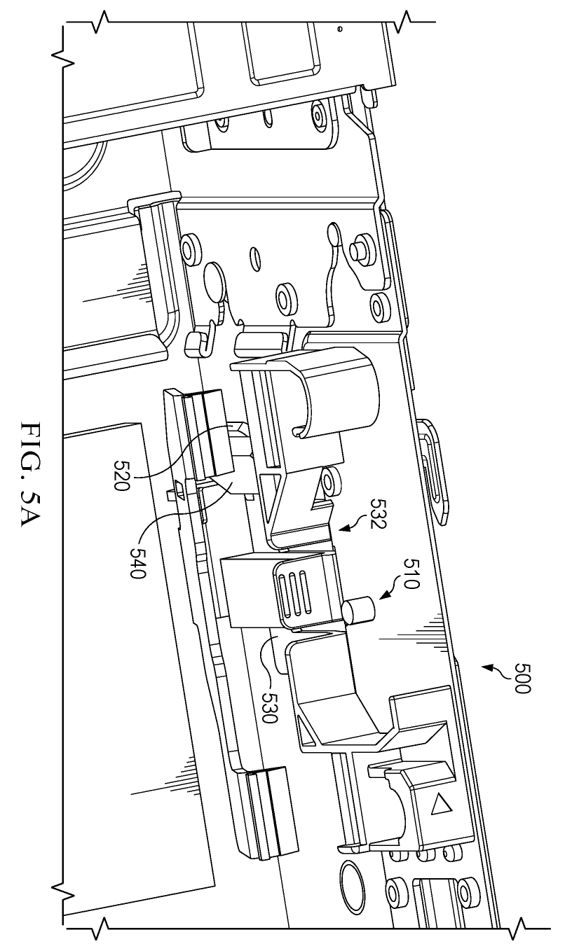

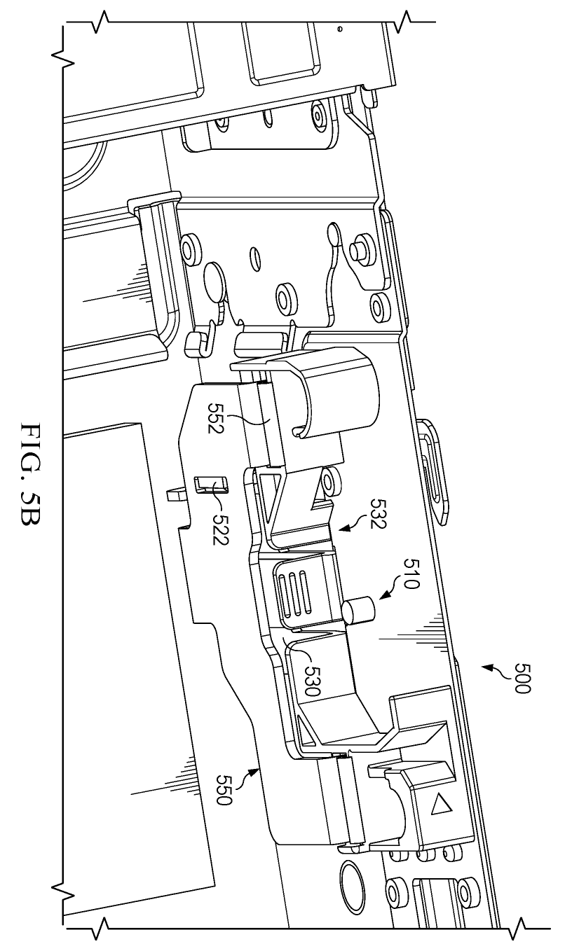

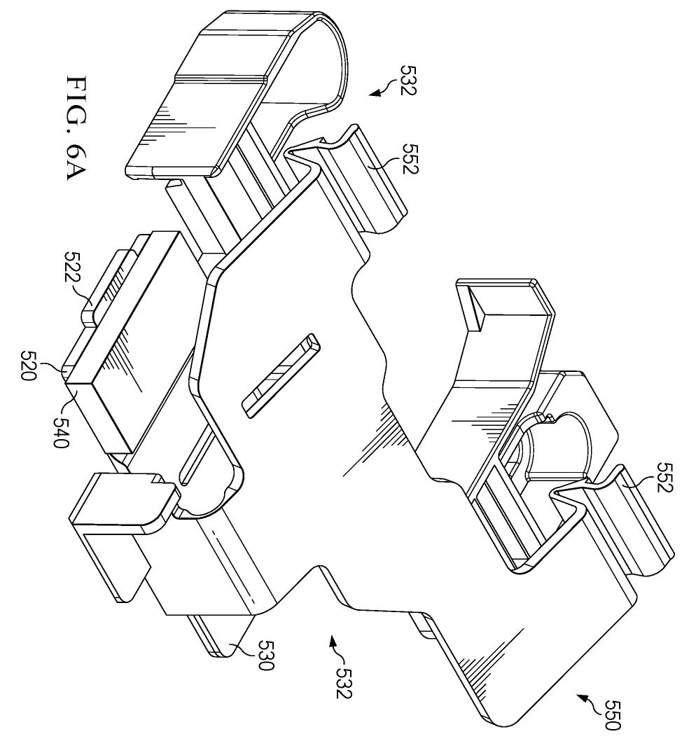

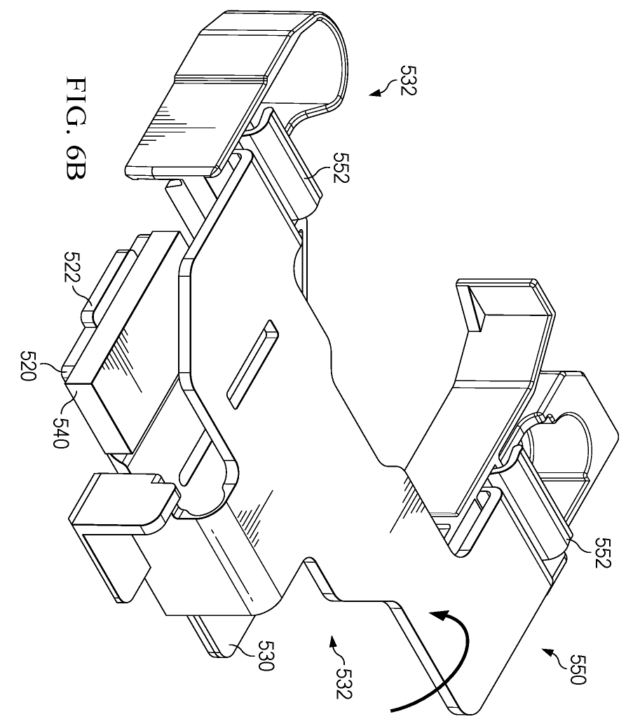

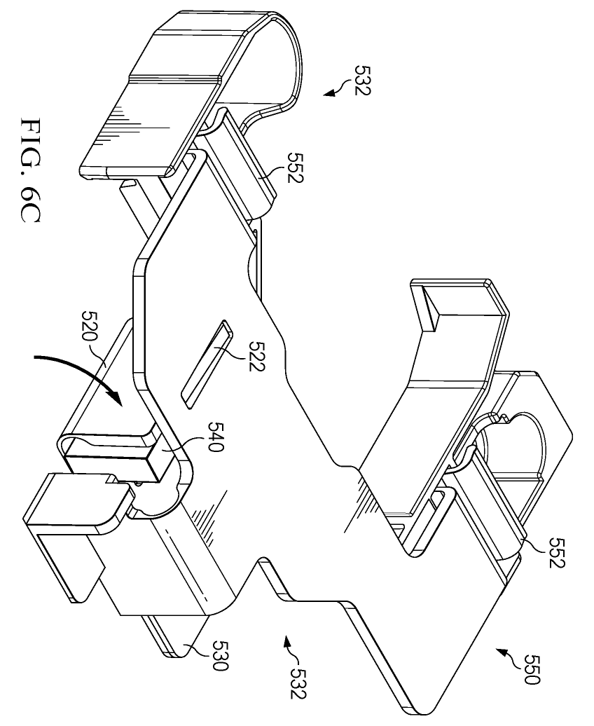

FIGS. 5A and 5B, generally referred to as FIG. 5, show perspective views of an internal portion of a server system 500 having a fan cage side wall system 510. FIGS. 6A and 6B, generally referred to as FIG. 6, show perspective views of a fan cage side wall system in an open configuration and a closed configuration, respectively. More specifically, FIGS. 5A and 6A show perspective views of the fan side wall component in an open configuration. FIG. 5B and 6B show perspective views of the fan side wall component in a closed configuration. In certain embodiments, the fan cage side wall system functions as a side wall block.

In certain embodiments, the fan cage side wall system 510 includes a rotational flapper 520. In certain embodiments, the rotational flapper 520 extends from a rear wall 530 of a rear housing component 532 of the fan cage side wall system 510. In certain embodiments, the rotational flapper 520 may be set to an open orientation (see e.g., FIG. 5A) so that the side wall block can be populated with cables. In certain embodiments, the rotational flapper 520 may be set to a closed orientation (see e.g., FIG. 5B) when the side wall block is not populated with cables. In certain embodiments, the rotational flapper being set to the closed orientation prevents airflow through the side wall block, thus improving the thermal performance of the fan cage side wall component.

In certain embodiments, the flapper 520 includes a flange 522. In certain embodiments, the flange 522 is configured as a projection edge which is used for attaching the flapper 522 when the flapper is in a closed orientation. In certain embodiments, the flapper interfaces with an elongated aperture 522 defined by the front wall when the flapper 522 is in the closed orientation.

In certain embodiments, the rotational flapper 520 is configured to include a thermal sealing component 540 which thermally seals the fan cage side wall system 510 when the side wall block is populated with cables. In certain embodiments, the thermal sealing component 540 includes a thermal sponge. In certain embodiments, the thermal sponge is thinner than previous thermal sealing solutions.

In certain embodiments, the rear housing component 532 is configured to include one or more thermal sealing components which thermally seal the fan cage side wall system when the side wall block is populated with cables. In certain embodiments, the thermal sealing components each include a thermal sponge. In certain embodiments, the thermal sponge is thinner than previous thermal sealing solutions and thermal sealing components are attached to rear housing component.

In certain embodiments, the fan cage side wall system 510 includes a front housing component 550. In certain embodiments, the front housing component 550 pivots between an open configuration and a closed configuration. In certain embodiments, when the front housing component 550 is in the closed configuration, connection latches 552 latch with the rear housing component 530. In certain embodiments, the front housing component 550 functions as a side wall block cover when the front housing component 550 is in the closed configuration. In certain embodiments, the front housing component 550 is contiguous with an outside side wall of the fan cage when the front housing component 550 is in a closed configuration and the fan cage is installed in the server system 500.

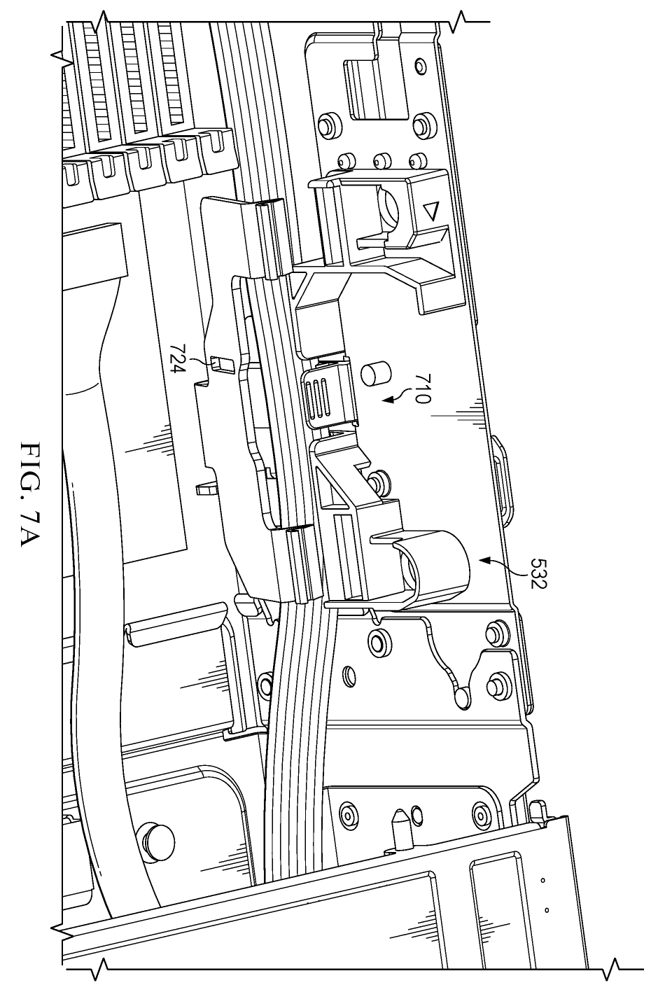

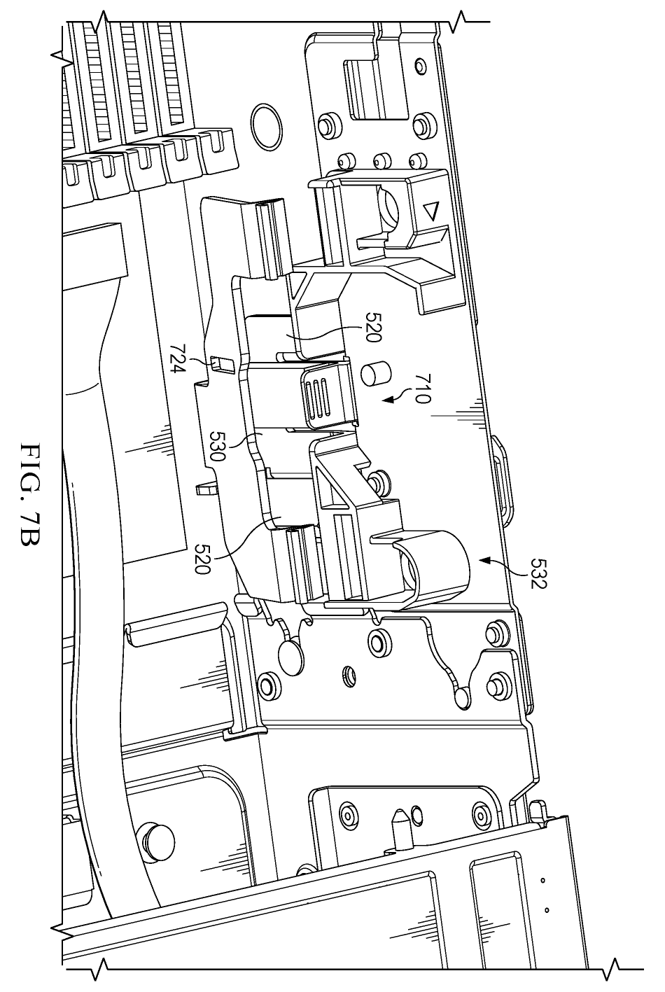

FIGS. 7A, 7B, 7C and 7D, generally referred to as FIG. 7, show perspective views of an internal portion of a server system having a fan cage side wall system. More specifically, FIG. 7A shows a perspective view of an internal portion of a server system and a fan cage side wall system when the fan cage side wall system is in a cable pass through configuration. FIG. 7B shows a side view of an internal portion of a server system and a fan cage side wall system when the fan cage side wall system is in a cable pass through configuration. FIG. 7C shows a perspective view of an internal portion of a server system and a fan cage side wall system when the fan cage side wall system is in a cableless configuration. FIG. 7D shows a side view of an internal portion of a server system and a fan cage side wall system when the fan cage side wall system is in a cableless configuration.

In certain embodiments, the fan cage side wall system 710 includes a rotational flapper 720. In certain embodiments, the rotational flapper 720 extends from a rear wall 730 of a rear housing component 732 of the fan cage side wall system 710. In certain embodiments, the rotational flapper 720 may be set to an open orientation (see e.g., FIG. 7A) so that the side wall block can be populated with cables. In certain embodiments, the rotational flapper 720 may be set to a closed orientation (see e.g., FIG. 7B) when the side wall block is not populated with cables. In certain embodiments, the rotational flapper being set to the closed orientation prevents airflow through the side wall block, thus improving the thermal performance of the fan cage side wall component.

In certain embodiments, when the fan cage side wall system 710 is in an open orientation, the rotational flapper 720 remains in an open position when the front housing component is latched when cables are routed through the fan cage side wall system.

In certain embodiments, when the fan cage side wall system 710 pivots from an open orientation to a closed orientation, the rotational flapper 720 pivots to a closed position when fan cage side wall system is functioning in a cableless configuration. In certain embodiments, the closed position of the rotational flapper 720 is substantially 90 degrees from the open position of the rotational flapper 720.

In certain embodiments, the flapper 720 includes a flange 722. In certain embodiments, the flange 722 is configured as a projection edge which is used for attaching the flapper 722 when the flapper is in a closed orientation. In certain embodiments, the flapper interfaces with an elongated aperture 724 defined by the front wall when the flapper 722 is in the closed orientation.

In certain embodiments, the rotational flapper 710 is configured to include a thermal sealing component 740 which thermally seals the fan cage side wall system 710 when the side wall block is populated with cables. In certain embodiments, the thermal sealing component 740 includes a thermal sponge. In certain embodiments, the thermal sponge is thinner than previous thermal sealing solutions.

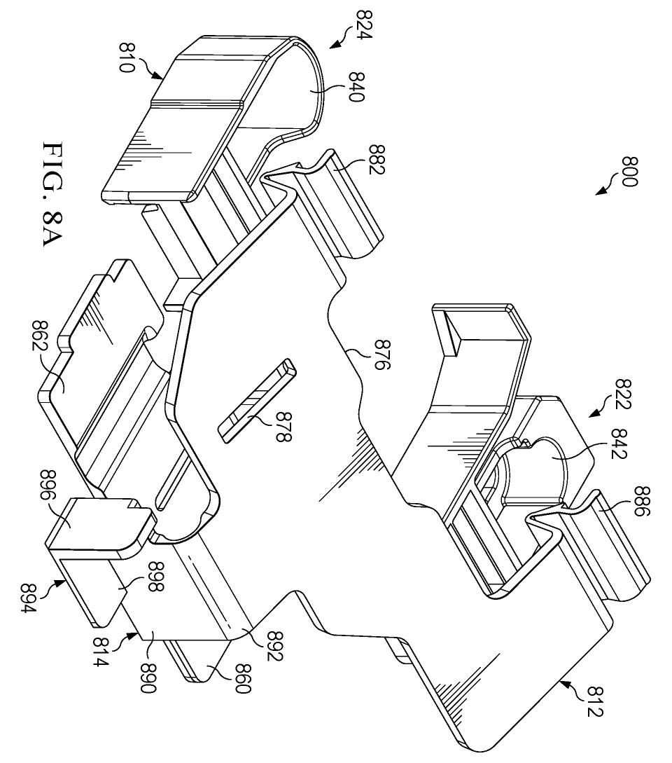

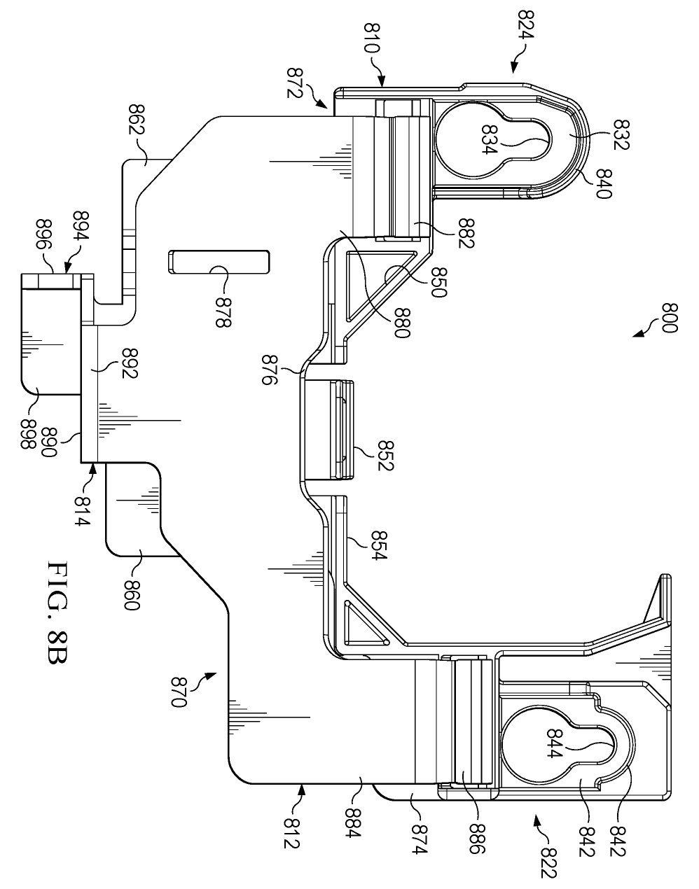

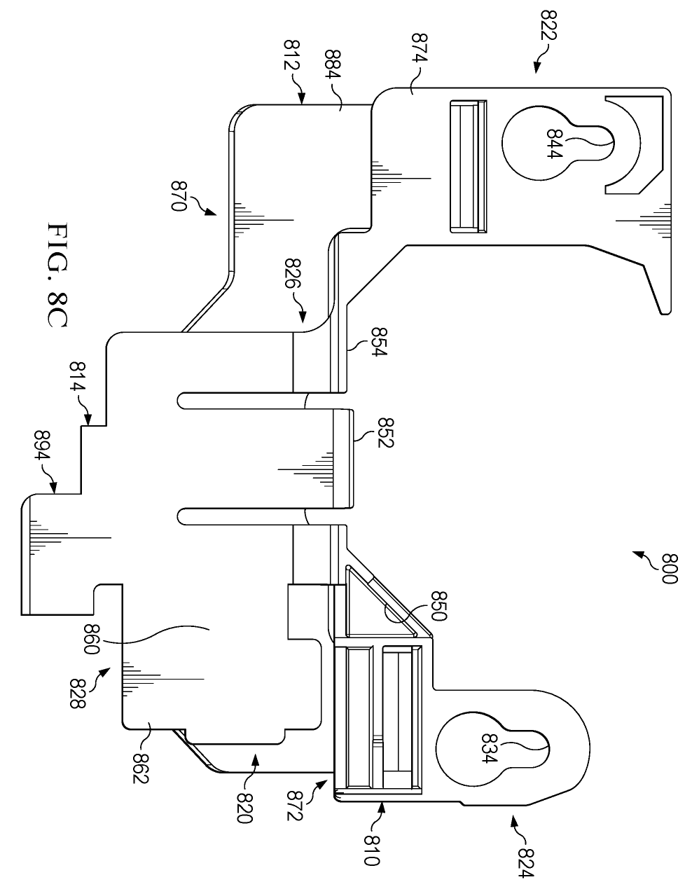

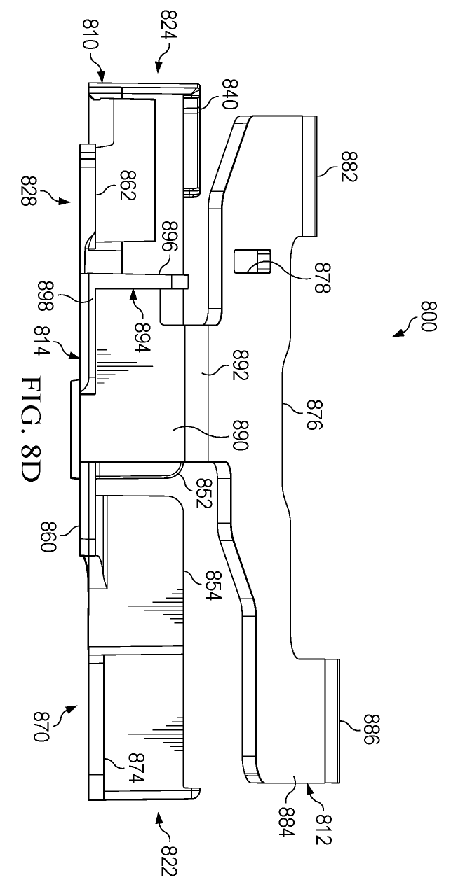

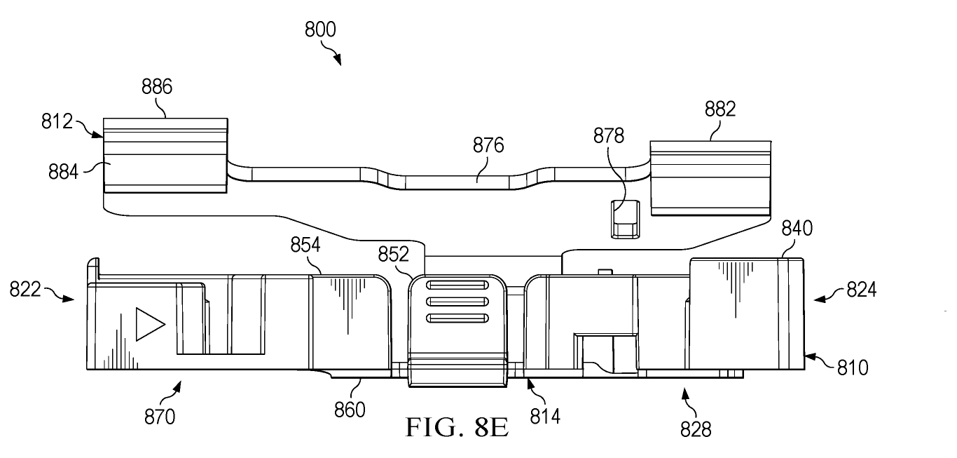

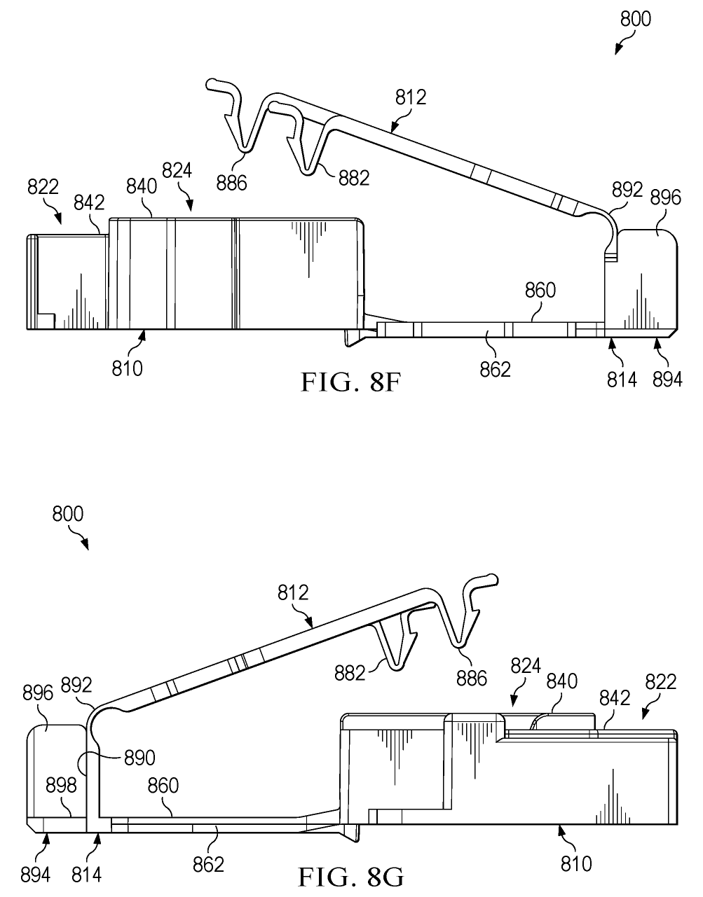

FIGS. 8A, 8B, 8C, 8D, 8E, 8F and 8G, generally referred to as FIG. 8, show a plurality of views of a fan cage side wall system 800 in an open configuration. More specifically, FIG. 8A shows a perspective view of a fan cage side wall system 800 in an open configuration. FIG. 8B shows a top view of a fan cage side wall system 800 in an open configuration. FIG. 8C shows a bottom view of a fan cage side wall system 800 in an open configuration. FIG. 8D shows a front view of a fan cage side wall system 800 in an open configuration. FIG. 8E shows a rear view of a fan cage side wall system 800 in an open configuration. FIG. 8F shows a left view of a fan cage side wall system 800 in an open configuration. FIG. 8G shows a right view of a fan cage side wall system 800 in an open configuration.

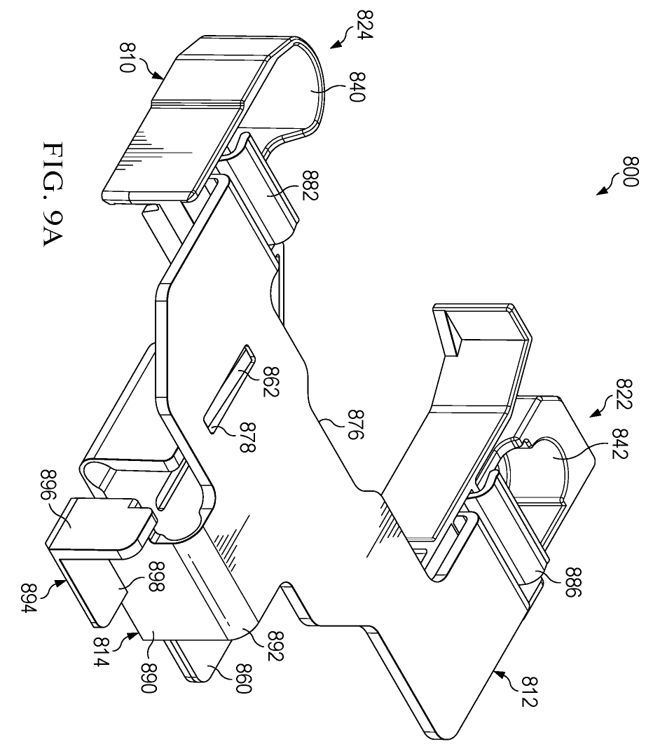

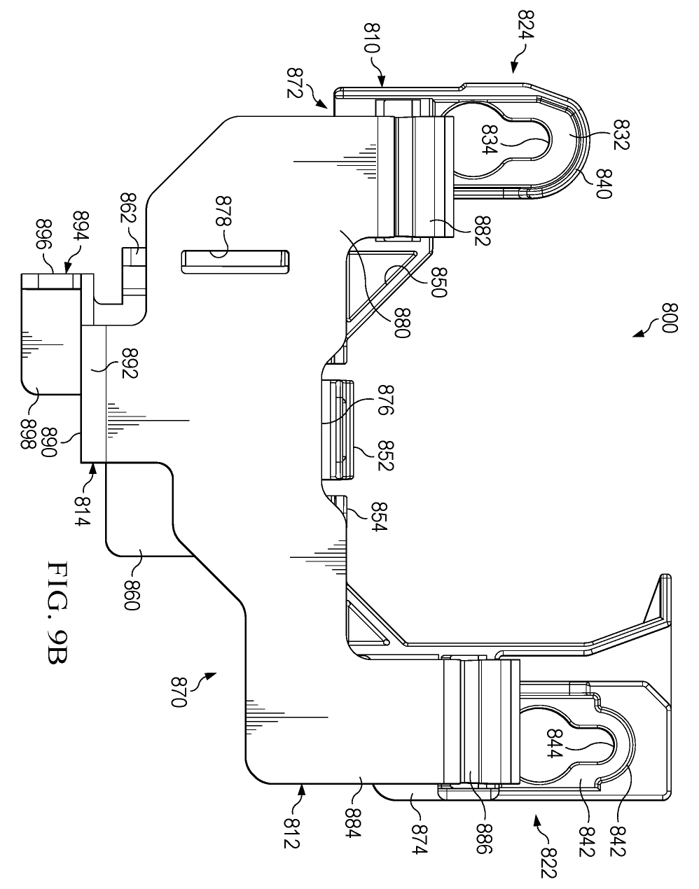

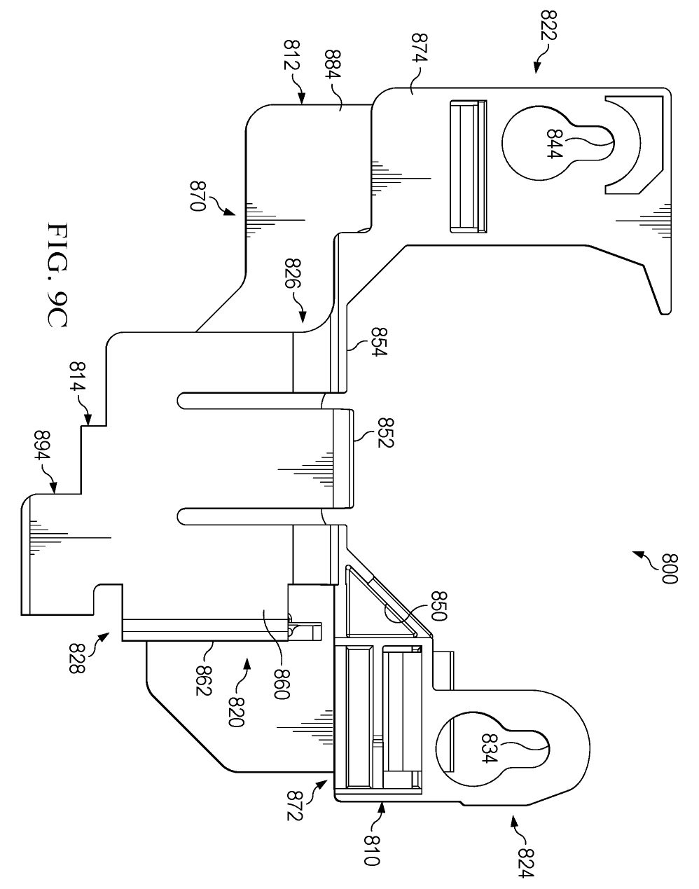

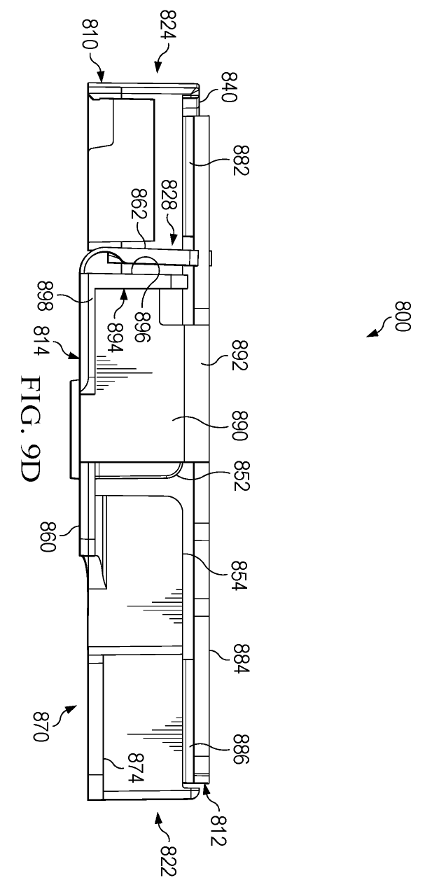

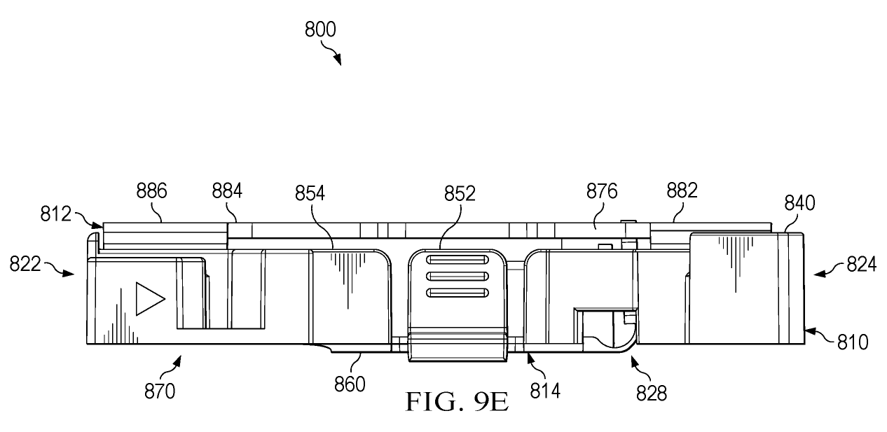

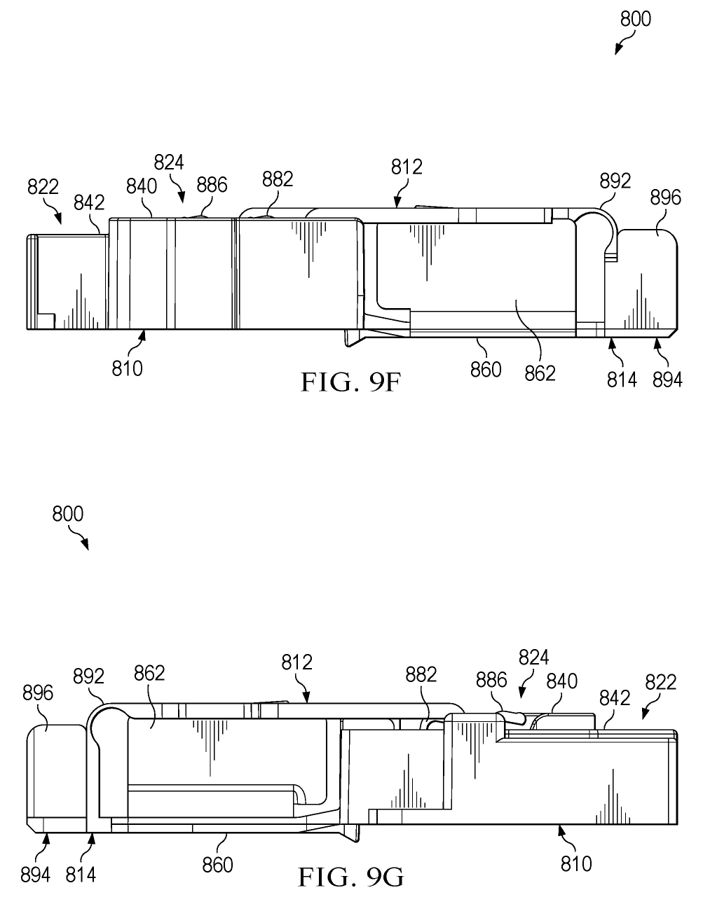

FIGS. 9A, 9B, 9C, 9D, 9E, 9F and 9G, generally referred to as FIG. 9, show a plurality of views of a fan cage side wall system 800 in a closed configuration. More specifically, FIG. 9A shows a perspective view of a fan cage side wall system 800 in a closed configuration. FIG. 9B shows a top view of a fan cage side wall system 800 in a closed configuration. FIG. 9C shows a bottom view of a fan cage side wall system 800 in a closed configuration. FIG. 9D shows a front view of a fan cage side wall system 800 in a closed configuration. FIG. 9E shows a rear view of a fan cage side wall system 800 in a closed configuration. FIG. 9F shows a left view of a fan cage side wall system 800 in a closed configuration. FIG. 9G shows a right view of a fan cage side wall system 800 in a closed configuration.

More specifically, the fan cage side wall system 800 includes a rear housing component 810, a front housing component 812, a bottom housing component 814, or a combination thereof. In certain embodiments, the bottom housing component 814 is physically coupled between the rear housing component and the front housing component. In certain embodiments, the bottom housing component 814 extends substantially perpendicularly between the rear housing component 810 and the front housing component 812. In certain embodiments, the rear housing component 810 and the front housing component 812 provide an airflow sealing portion (see e.g., FIGS. 8F and 8G). In certain embodiments, the rear housing component 810, the front housing component 812, and the bottom housing component 814 provide a cable routing portion (see e.g., FIGS. 9F and 9G).

In certain embodiments, the rear housing component 810 includes a rear wall 820, a first top rear housing portion 822, a second top rear housing portion 824, a mid rear wall housing portion 826, a lower rear wall housing portion 828, or a combination thereof. In certain embodiments, the mid rear housing portion 826 is positioned laterally between the first top rear housing portion 822 and the second top rear housing portion 824. In certain embodiments, the lower rear housing portion 826 is positioned beneath between the first top rear housing portion 822, the second top rear housing portion 824, and the mid rear wall housing portion 826.

In certain embodiments, the first top rear housing portion 822 includes a wall 830 extending around a first extension 832 of the rear wall 820. In certain embodiments, the wall extends substantially perpendicularly from the first extension 832 of the rear wall. In certain embodiments, the wall 830 includes a somewhat semi-circular looped portion, a first flat portion, a second flat portion, or a combination thereof. In certain embodiments, the first extension 832 of the rear wall 820 defines an attachment aperture 834. In certain embodiments, a fastener may be passed through the attachment aperture 834 to attach the fan cage side wall system 800 to an inside wall of a server system chassis. In certain embodiments, the first top rear housing portion defines a first latching recess 836. In certain embodiments, the first latching recess 836 includes a substantially rectangular opening.

In certain embodiments, the second top rear housing portion 824 includes a wall 840 extending around a second extension 842 of the rear wall 820. In certain embodiments, the wall 840 extends substantially perpendicularly from the second extension 842 of the rear wall. In certain embodiments, the wall 840 includes a somewhat semi-circular looped portion, a first flat portion, a second flat portion, or a combination thereof. In certain embodiments, the second extension 842 of the rear wall 820 defines an attachment aperture 844. In certain embodiments, a fastener may be passed through the attachment aperture 844 to attach the fan cage side wall system 800 to an inside wall of a server system chassis. In certain embodiments, the second top rear housing portion defines a second latching recess 846. In certain embodiments the second latching recess 846 includes a substantially rectangular opening.

In certain embodiments, the mid rear wall housing portion 826 includes a first cable routing component 850, a mid cable routing component 852, a second cable routing component 854, or a combination thereof. In certain embodiments, the first cable routing component 850, the mid cable routing component 852, the second cable routing component 854, or a combination thereof, combine to provide a top wall of the cable routing portion of the fan cage side wall system 800.

In certain embodiments, the lower rear wall housing portion 828 includes a lower rear wall 860, a rotational flapper 862, or a combination thereof. In certain embodiments, the rotational flapper 860 extends from the lower rear wall 860 of the lower rear wall housing portion 828. In certain embodiments, the rotational flapper 862 may be set to an open orientation (see e.g., FIG. 8A) so that the cable routing portion can be populated with cables. In certain embodiments, the rotational flapper 862 may be set to a closed orientation (see e.g., FIG. 9A) when the cable routing portion is not populated with cables. In certain embodiments, the rotational flapper being set to the closed orientation restricting airflow through the side wall block, thus functioning as part of the airflow sealing portion. In certain embodiments, the flapper interfaces with an elongated aperture 822 defined by the front wall when the flapper 822 is in the closed orientation. In certain embodiments, the flapper 862 includes a flange 864. In certain embodiments, the flange 864 is configured as a projection edge which is used for attaching the flapper 862 when the flapper 862 is in a closed orientation.

In certain embodiments, the front housing component 812 pivots between an open configuration (see e.g., FIG. 8A) and a closed configuration (see e.g., FIG. 9A). In certain embodiments, the front housing component 812 includes a front wall 870, a first top front housing portion 872, a second top front housing portion 874, or a combination thereof. In certain embodiments, the front wall 870 is positioned laterally between the first top front housing portion 872 and the second top front housing portion 874.

In certain embodiments, the front wall 870 includes a top edge 876 which includes a central indented portion. In certain embodiments, the front wall 870 defines an elongated aperture 878. In certain embodiments, the flapper interfaces with the elongated aperture 878 defined by the front wall 870 when the flapper 862 is in the closed orientation.

In certain embodiments, the first top front housing portion 872 includes a first top front wall 880, a first connection latch 882, or a combination thereof. In certain embodiments, the first connection latch 882 projects inwardly from the first top front wall 880. In certain embodiments, the first top front wall 880 is contiguous with and continuous with the front wall 880. In certain embodiments, the second top front housing portion 874 includes a second top front wall 884, a second connection latch 886, or a combination thereof. In certain embodiments, the second connection latch 886 projects inwardly from the second top front wall 884. In certain embodiments, the second top front wall 884 is contiguous with and continuous with the front wall 880.

In certain embodiments, when the front housing component 812 is in the closed configuration (see e.g., FIG. 9A), the first connection latch 880 interacts with the first latching recess 836 to removably affix the front housing component 812 to the rear housing component 810. In certain embodiments, when the front housing component 812 is in the closed configuration, the second connection latch 886 interacts with the second latching recess 846 to removably affix the front housing component 812 to the rear housing component 810.

In certain embodiments, the bottom housing component 814 includes a bottom wall 890, a pivot portion 892, an airflow restriction component 894, or a combination thereof. In certain embodiments, the pivot portion 892 extends across an edge of the bottom wall 890. In certain embodiments, the pivot portion 892 is contiguous with an edge of the front housing component 912. In certain embodiments, the pivot portion 892 allows the front housing component to pivot between an open orientation and a closed orientation. In certain embodiments, the airflow restriction component 894 extends substantially perpendicularly from the bottom wall 890. In certain embodiments, the airflow restriction component 894 includes a first wall portion 896, a second wall portion 898, or a combination thereof. In certain embodiments, the first wall portion 896 and the second wall portion 898 are positioned substantially perpendicularly with each other. In certain embodiments, the first wall portion 896 and the second wall portion 898 are positioned to abut an inside wall of an information handling system chassis, a bottom wall of an information handling system chassis, or a combination thereof.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

1. A fan cage side wall system, comprising:
a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system;
a front housing component; and,
a bottom housing component, the bottom housing component being physically coupled between the rear housing component and the front housing component.

2. The fan cage side wall system of claim 1, wherein:
the rear housing component comprises a rear wall; and,
the flapper component extending from the rear wall of the rear housing component.

3. The fan cage side wall system of claim 2, wherein:
the rear housing component comprises a top rear housing component, the top rear housing component comprising a first extension and a wall extending substantially perpendicularly from the first extension, the wall extending substantially from the first extension restricting air flow through the fan cage side all system.

4. The fan cage side wall system of claim 1, wherein:
the front housing component comprises a front wall; and,
the front wall defines an aperture, the aperture interacting with the flapper when the flapper is in the closed orientation.

5. The fan cage side wall system of claim 1, wherein:
the flapper comprises a flange extending alone and edge of the flapper; and,
the flange mates with the aperture defined by the front wall when the flapper is in the closed orientation.

6. The fan cage side wall system of claim 1, wherein:
the bottom housing component comprises a bottom wall and a pivot portion contiguous with an edge of the bottom wall, the pivot portion allowing the front housing component to pivot between an open configuration and a closed configuration.

7. A thermal system comprising:
a fan cage; and,
a fan cage side wall system positioned between the fan cage and a wall of an information handling system chassis, the fan cage side wall system comprising
a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system;
a front housing component; and,
a bottom housing component, the bottom housing component being physically coupled between the rear housing component and the front housing component.

8. The thermal system of claim 7, wherein:
the rear housing component comprises a rear wall; and,
the flapper component extending from the rear wall of the rear housing component.

9. The thermal system of claim 8, wherein:
the rear housing component comprises a top rear housing component, the top rear housing component comprising a first extension and a wall extending substantially perpendicularly from the first extension, the wall extending substantially from the first extension restricting air flow through the fan cage side all system.

10. The thermal system of claim 7, wherein the fan system gantry component further comprises:
the front housing component comprises a front wall; and,
the front wall defines an aperture, the aperture interacting with the flapper when the flapper is in the closed orientation.

11. The thermal system of claim 8, wherein:
the flapper comprises a flange extending alone and edge of the flapper; and,
the flange mates with the aperture defined by the front wall when the flapper is in the closed orientation.

12. The thermal system of claim 7, wherein:
the bottom housing component comprises a bottom wall and a pivot portion contiguous with an edge of the bottom wall, the pivot portion allowing the front housing component to pivot between an open configuration and a closed configuration.

13. A system comprising:
a processor;
a data bus coupled to the processor;
a thermal system comprising
a fan cage; and,
a fan cage side wall system positioned between the fan cage and a wall of an information handling system chassis, the fan cage side wall system comprising
a rear housing component, the rear housing component comprising a rotational flapper, the rotational flapper being configured to be set to one of an open orientation and a closed orientation, the open orientation allowing the fan case side wall system to be populated with a cable, the closed orientation restricting air flow through the fan cage side all system;
a front housing component; and,
a bottom housing component, the bottom housing component being physically coupled between the rear housing component and the front housing component.

14. The system of claim 13, wherein:
the rear housing component comprises a rear wall; and,
the flapper component extending from the rear wall of the rear housing component.

15. The system of claim 14, wherein:
the rear housing component comprises a top rear housing component, the top rear housing component comprising a first extension and a wall extending substantially perpendicularly from the first extension, the wall extending substantially from the first extension restricting air flow through the fan cage side all system.

16. The system of claim 13, wherein:
the front housing component comprises a front wall; and,
the front wall defines an aperture, the aperture interacting with the flapper when the flapper is in the closed orientation.

17. The system of claim 16, wherein the fan system gantry component further comprises:
the flapper comprises a flange extending alone and edge of the flapper; and,
the flange mates with the aperture defined by the front wall when the flapper is in the closed orientation.

18. The system of claim 13, wherein the fan system gantry component further comprises:
the bottom housing component comprises a bottom wall and a pivot portion contiguous with an edge of the bottom wall, the pivot portion allowing the front housing component to pivot between an open configuration and a closed configuration.
